(19) United States
(12) Patent Application Publication
(10) Pub. No.: US 2026/0247847 A1
(43) Pub. Date: Aug. 20, 2026

(54) DISPLAY DEVICE, ELECTRONIC DEVICE INCLUDING DISPLAY DEVICE, AND METHOD OF MANUFACTURING DISPLAY DEVICE

(71) Applicant: Samsung Display Co., Ltd., Yongin-si (KR)

(72) Inventors: Hyojeong KWON, Yongin-si (KR); Ohjune Kwon, Yongin-si (KR); Woo Yong Sung, Yongin-si (KR); Soomin Oh, Yongin-si (KR); Kwanhyuck Yoon, Yongin-si (KR); Jeongseok Lee, Yongin-si (KR); Hyemin Lee, Yongin-si (KR); Seunggun Chae, Yongin-si (KR); Sangyeon Hwang, Yongin-si (KR)

(73) Assignee: Samsung Display Co., Ltd., Yongin-si (KR)

(21) Appl. No.: 19/391,048

(22) Filed: Nov. 17, 2025

(30) Foreign Application Priority Data
Feb. 17, 2025 (KR) 10-2025-0019842

(51) Int. Cl. H10K 59/80; H10K 59/12; H10K 71/40; H10K 71/80

(52) U.S. Cl. CPC H10K 59/8792; H10K 59/1201; H10K 71/421; H10K 71/80

(57) ABSTRACT

Disclosed is a display device including a substrate which includes an upper surface and a lower surface opposite the upper surface, the substrate including a groove extending along an edge of the lower surface, a light emitting element layer on the upper surface of the substrate, and a light shielding layer on the lower surface of the substrate in at least a portion of the groove.

### CROSS-REFERENCE TO RELATED APPLICATIONS

This application claims priority under 35 U.S.C. § 119 to Korean Patent Application No. 10-2025-0019842 filed on February 17, 2025, in the Korean Intellectual Property Office, the disclosures of which are incorporated by reference herein in their entireties.

### BACKGROUND

Embodiments of the present disclosure described herein relate to a display device, an electronic device including the same, and a method of manufacturing the display device, and more particularly, relate to a display device including a glass substrate that improves a light shielding effect of a light shielding layer, and an electronic device including the same.

In a display module, a light shielding layer may be attached to a light emitting opposite surface to reduce reflection of external light, and an internal light source may be prevented from unnecessarily leaking to the outside to improve image quality. The light shielding layer may reduce an interference phenomenon that may occur inside the display device, thereby ensuring accurate color expression and clarity.

### SUMMARY

Embodiments of the present disclosure may provide a display device having an improved light shielding effect.

Embodiments of the present disclosure may also provide an electronic device including the display device.

Embodiments of the present disclosure may also provide a method of manufacturing a display device having an improved light shielding effect.

According to an embodiment, a display device may include a substrate which includes an upper surface and a lower surface opposite the upper surface, the substrate including a groove extending along an edge of the lower surface, a light emitting element layer on the upper surface of the substrate, and a light shielding layer on the lower surface, at least a portion of the light shielding layer being filled in at least a portion of the groove.

According to an embodiment of the present disclosure, the groove may divide the lower surface into an inner area and an outer area, and the light shielding layer may be in the inner area.

According to an embodiment of the present disclosure, the light shielding layer may have the same thickness in an area not overlapping the groove.

According to an embodiment of the present disclosure, the groove may have a width of about 10 μm

According to an embodiment of the present disclosure, the groove may have a closed-loop shape in a plan view of the lower surface of the substrate.

According to an embodiment of the present disclosure, the groove may include a first edge adjacent the edge of the lower surface and a second edge farther from the edge of the lower surface than the first edge, and a distance between the edge of the lower surface and the first edge may be about 0.4 mm or less.

According to an embodiment of the present disclosure, the light shielding layer may include a base resin and a black component mixed with the base resin.

According to an embodiment of the present disclosure, the groove may include a first groove and a second groove, and the second groove may be closer to an edge of the substrate than the first groove.

According to an embodiment of the present disclosure, each of the first groove and the second groove may have a width of about 10 μm.

According to an embodiment of the present disclosure, a partial area of the light shielding layer may overlap any one of the first groove or the second groove.

According to an embodiment, an electronic device may include a display device, and a processor that controls the display device, wherein the display device includes a substrate including an upper surface and a lower surface opposite the upper surface, the substrate including a groove adjacent an edge thereof, a light emitting element layer on the upper surface of the substrate, and a light shielding layer on the lower surface , and a partial area of the light shielding layer overlaps a partial area of the groove.

According to an embodiment of the present disclosure, the groove may have a closed-loop shape in a plan view of the lower surface of the substrate.

According to an embodiment of the present disclosure, the groove may have a width of about 10 μm.

### BRIEF DESCRIPTION OF DRAWINGS

The above and other objects and features of the present disclosure will become apparent by describing in detail embodiments thereof with reference to the accompanying drawings.

FIG. 1 is a block diagram of an electronic device according to an embodiment of the present disclosure.

FIG. 2 is a schematic view of the electronic device according to an embodiment.

FIG. 3 is a perspective view of a display device according to an embodiment of the present disclosure.

FIG. 4 is a cross-sectional view corresponding to line I-I' in FIG. 3.

FIG. 5A is an enlarged cross-sectional view of a portion of the display device according to an embodiment.

FIG. 5B is a rear view of the portion of the display device according to an embodiment.

FIG. 6A is an enlarged cross-sectional view of the portion of the display device according to an embodiment.

FIG. 6B is a rear view of the portion of the display device according to an embodiment.

FIGS. 7A to 7I are cross-sectional views illustrating a method of manufacturing a display device according to an embodiment of the present disclosure.

### DETAILED DESCRIPTION

In the specification, the expression that a first component (or an area, a layer, a part, a portion, etc.) is “disposed on”, “connected with” or “coupled to” a second component may mean that the first component is directly disposed on/connected with/coupled to the second component or may mean that a third component is interposed therebetween.

In the detailed description and the accompanying drawings, the same reference numerals refer to the same components. Further, in the drawings, the thickness, the ratio, and the dimensions of components may be exaggerated for effective description of technical contents. The term “and/or” may include all combinations of one or more components that may be defined by associated components.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may also be referred to as the first component. Singular expressions include plural expressions unless clearly otherwise indicated in the context.

Also, the terms “under”, “below”, “on”, “above”, etc. may be used to describe the correlation of components illustrated in drawings. The terms that are relative in concept may be described based on a direction illustrated in drawings.

It will be understood that the terms “include”, “comprise”, “have”, etc. may specify the presence of features, numbers, steps, operations, elements, or components, described in the specification, or a combination thereof, and may not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs. Further, terms (including those defined in commonly used dictionaries) should be interpreted as having a meaning consistent with the meaning in the context of the related technology and should not be interpreted in overly ideal or overly formal meanings unless explicitly defined herein.

Hereinafter, an embodiment of the present disclosure will be described with reference to the accompanying drawings.

The display device according to an embodiment may be applied to various electronic devices. The electronic device according to an embodiment may include the display device and may further include a module or a device having another additional function in addition to the display device.

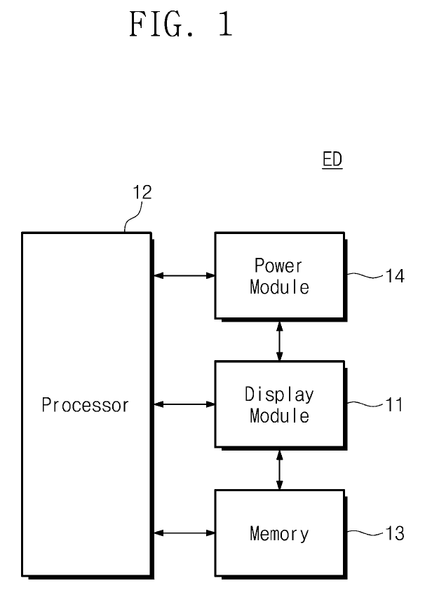

FIG. 1 is a block diagram of an electronic device according to an embodiment of the present disclosure. Referring to FIG. 1, an electronic device ED according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information required for operations of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device and a power conversion module that converts power supplied by the power supply module to generate power required for the operation of the electronic device 10.

At least one of the components of the electronic device ED may be included in the display device according to an embodiment. Further, some of individual modules functionally included inside one module may be included inside the display device, and the others thereof may be provided separately from the display device. For example, the display device may include the display module 11, and the processor 12, the memory 13, and the power module 14 may be provided in the form of other devices in the electronic device ED rather than the display device.

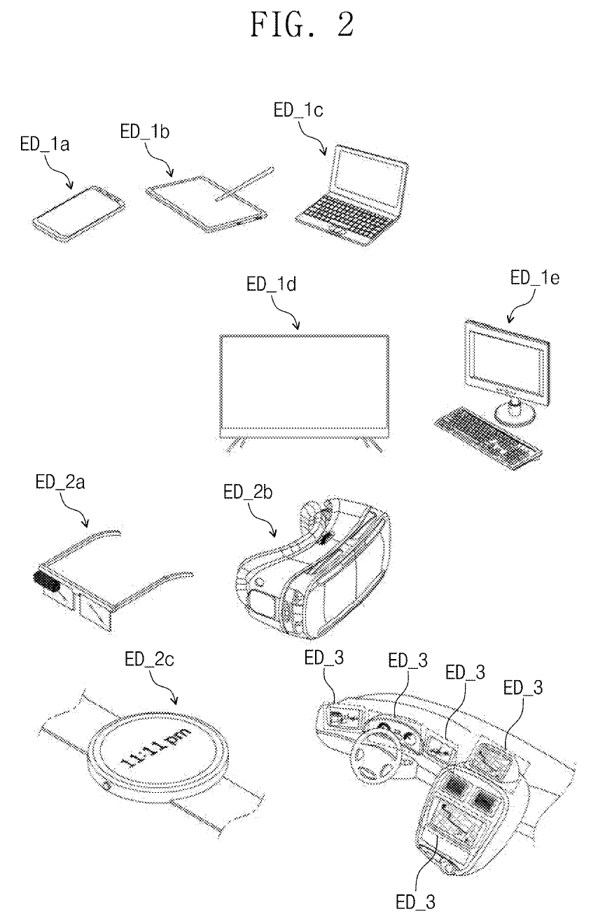

FIG. 2 is a schematic view of the electronic device according to an embodiment.

Referring to FIG. 2, various electronic devices to which the display device according to an embodiment is applied may include an image display electronic device such as a smartphone ED_1a, a tablet personal computer (PC) ED_1b, a laptop computer ED_1c, a television (TV) ED_1d, and a desk monitor ED_1e, a wearable electronic device including a display module such as a smart glasses ED_2a, a head mounted display ED_2b, and a smart watch ED_2c, and a vehicle electronic device ED_3 including a display module such as an instrument panel, a center fascia, a center information display (CID) disposed on a dashboard, and a room mirror display of a vehicle.

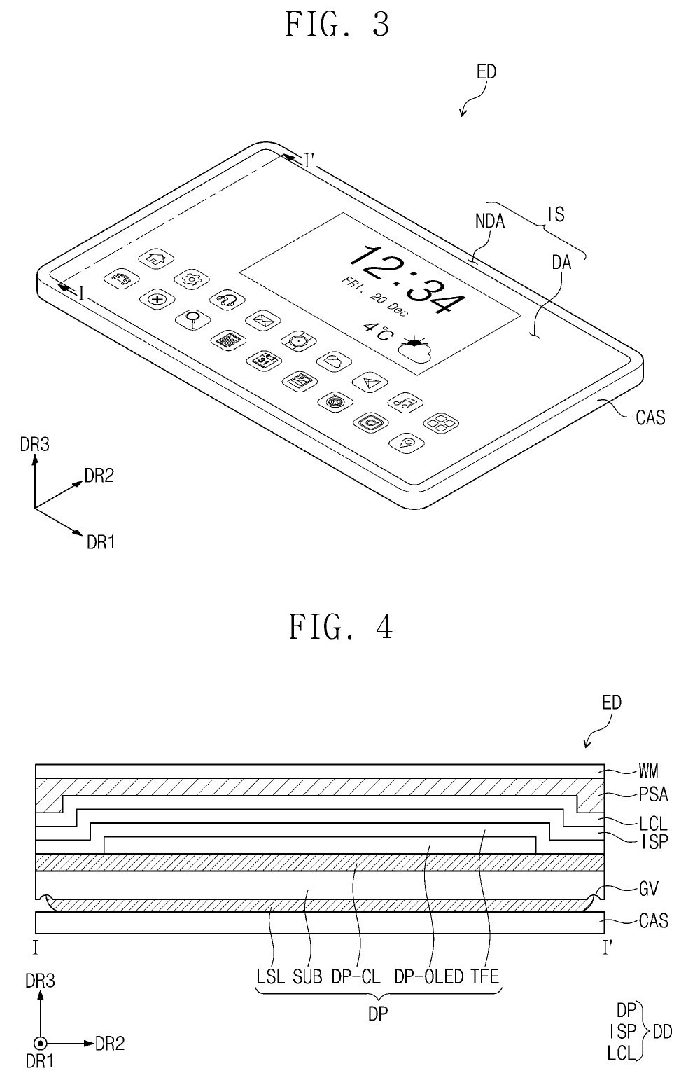

FIG. 3 is a perspective view of a display device according to an embodiment of the present disclosure.

FIG. 3 illustrates, by way of example, an electronic device ED that may be applied to a tablet terminal. FIG. 4 is a cross-sectional view corresponding to line I-I' in FIG. 3.

Referring to FIGS. 3 and 4 together, the electronic device ED may include a case CAS, a display device DD disposed inside the case CAS, and a window WM disposed on the display device DD. Referring to FIG. 4, in a third direction DR3, the display device DD may be disposed on the case CAS, and the window WM may be disposed on the display device DD. The display device DD may have an adhesive layer PSA disposed on the window WM and thus may be coupled to the window WM. The window WM and the case CAS may be coupled to each other to form an external appearance of the electronic device ED.

Referring to FIG. 3, the electronic device ED may have a rectangular shape having long sides extending in a first direction DR1 and short sides extending in a second direction DR2 intersecting the first direction DR1. However, the present disclosure is not limited thereto, and the electronic device ED may have various shapes such as a circular shape or a polygonal shape. Hereinafter, a direction substantially perpendicular to a plane defined by the first direction DR1 and the second direction DR2 is defined as the third direction DR3. In the specification, the meaning of “on a plane” is defined as a state of being viewed in the third direction DR3.

The case CAS may accommodate the display device DD and may be coupled to the window WM. The case CAS may protect components, such as the display device DD, accommodated in the case CAS.

Electronic modules, camera modules, power modules, and the like mounted on a main board may be arranged on the case CAS together with the display device DD to constitute the tablet terminal. Meanwhile, an embodiment is not limited thereto, and the electronic device ED may be applied to large electronic devices such as televisions and monitors as well as small and medium-sized electronic devices such as mobile phones, car navigation systems, game consoles, and smart watches.

In a state in which the display device DD is coupled to the case CAS, a display surface IS may be exposed. As illustrated in FIG. 3, the display surface IS may include an active area DA on which an image is displayed and a bezel area NDA adjacent to the active area DA. The bezel area NDA is an area in which an image is not displayed. FIG. 3 illustrates icon images as an example of an image.

As illustrated in FIG. 3, the active area DA may have a substantially quadrangular shape. The wording “substantially quadrangular shape” includes not only a quadrangular shape in the mathematical sense, but also a quadrangular shape in which no vertex is defined in a vertex area (or corner area) and a boundary of a curved line is defined.

The bezel area NDA may surround the active area DA. However, the present disclosure is not limited thereto, and a shape of the bezel area NDA may be modified. For example, the bezel area NDA may be disposed only on one side of the active area DA.

The window WM may include an optically transparent material. The window WM may include an insulating panel. For example, the window WM may be made of glass, plastic, or a combination thereof. As described above, a front surface of the window WM may define a front surface of the electronic device ED. The window WM may include an optically transparent area. For example, the optically transparent area included in the window WM may be an area having a visible light transmittance of about 90% or more.

Referring to FIG. 4, the display device DD may include a display panel DP and an input sensing layer ISP. In an embodiment, the display device DD may further include a light control member LCL. In an embodiment, the display panel DP may include a light shielding layer LSL, a substrate SUB, a circuit element layer DP-CL, a light emitting element layer DP-OLED, and a thin film encapsulation layer TFE.

The light shielding layer LSL may be disposed on the case CAS. The light shielding layer LSL may be accommodated in the case CAS. The light shielding layer LSL may include a base resin and a black component mixed with the base resin, and may block external light and prevent leakage of internal light. The light shielding layer LSL may alleviate an impact generated in a lower portion of the electronic device ED to prevent damage to the display panel DP.

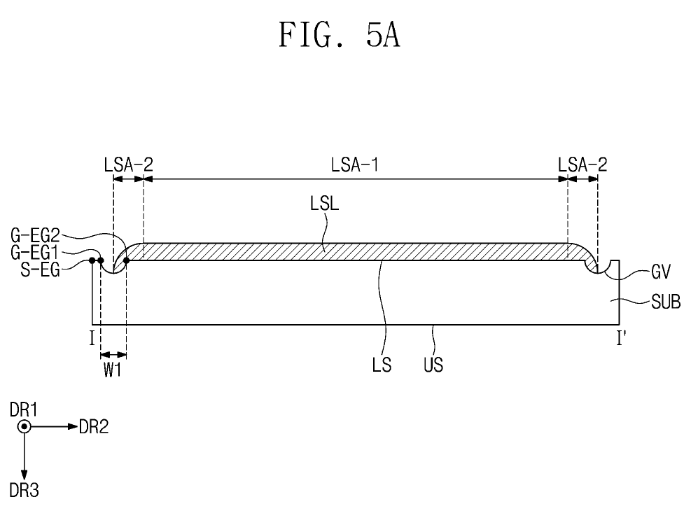

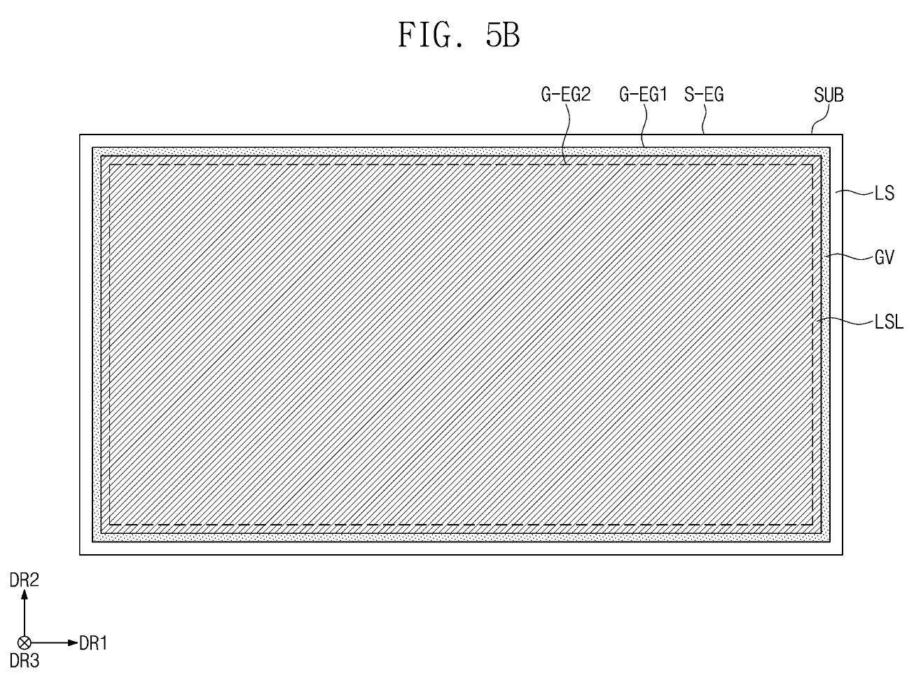

The substrate SUB may comprise a glass substrate, a metal substrate, or a polymer substrate. However, an embodiment is not limited thereto, and the substrate SUB may be an inorganic layer, an organic layer, or a composite material layer. The substrate SUB may have substantially the same shape as the display panel DP. The substrate SUB of the present invention may include a groove GV adjacent to an edge. A detailed description of a shape, arrangement, and the like of the groove GV will be described below with reference to FIGS. 5A and 5B.

The circuit element layer DP-CL may be disposed on the substrate SUB. The circuit element layer DP-CL may include a plurality of insulating layers, a plurality of semiconductor patterns, a plurality of conductive patterns, and signal lines. The circuit element layer DP-CL may include a driving circuit of a pixel.

The light emitting element layer DP-OLED may be disposed on the circuit element layer DP-CL. The light emitting element layer DP-OLED may include a light emitting element. For example, the light emitting element may include an organic light emitting material, an inorganic light emitting material, an organic-inorganic light emitting material, a quantum dot, a quantum rod, a micro light emitting diode (LED), or a nano LED.

The thin film encapsulation layer TFE may be disposed on the light emitting element layer DP-OLED. The thin film encapsulation layer TFE may protect the light emitting element layer DP-OLED (i.e., a light emitting element) from foreign substances such as moisture, oxygen, and dust particles. The thin film encapsulation layer TFE may include at least one inorganic encapsulation layer. The thin film encapsulation layer TFE may include a laminated structure of a first encapsulation inorganic layer/an organic encapsulation organic layer/and a second inorganic encapsulation layer.

The input sensing layer ISP may be directly disposed on the display panel DP. The input sensing layer ISP may sense an input of a user using, for example, an electromagnetic induction method and/or a capacitance method. The display panel DP and the input sensing layer ISP may be formed through a continuous process. Here, the fact that “the input sensing layer ISP is directly disposed on the display panel DP” may mean that no third component is disposed between the input sensing layer ISP and the display panel DP. For example, no separate adhesive layer may be disposed between the input sensing layer ISP and the display panel DP.

The light control member LCL may be a reflection reducing layer that reduces reflectance of external light by light incident from the outside of the display device DD. However, an embodiment is not limited thereto, and the light control member LCL may include components of various light control layers for improving display quality of the display device DD. For example, the light control member LCL according to an embodiment may include a polarizing layer, a phase retarder, a destructive interference structure, or a plurality of color filters. Meanwhile, in the electronic device ED according to an embodiment, the light control member LCL may be omitted.

Meanwhile, in the specification, the wording “an area/part corresponds to an area/part” may mean that “an area/part and an area/part overlap each other” and is not limited to a state in which the area/part and the area/part have the same area and/or the same shape.

FIG. 5A is an enlarged cross-sectional view of a portion of the display device according to an embodiment, and FIG. 5B is a rear view of the portion of the display device according to an embodiment. The display device of FIGS. 5A and 5B may represent the display device of FIG. 4.

FIG. 5A is a view illustrating a state in which the substrate SUB and the light shielding layer LSL of FIG. 4 are turned over in the third direction DR3. Referring to FIG. 5A, the substrate SUB may include an upper surface US and a lower surface LS opposite to the upper surface US. The groove GV extending along an edge of the lower surface LS may be defined on the lower surface LS on a plane.

The groove GV refers to a groove recessed in the third direction DR3 toward the upper surface US from the lower surface LS of the substrate SUB. A depth of the groove GV may be in a range of 10 μm to 50 μm. Referring to FIG. 5B, the groove GV may extend in the first direction DR1 and the second direction DR2 and may be substantially parallel to an edge of the substrate SUB. When viewed in the third direction DR3, the groove GV has a closed-loop shape on a plane on the lower surface LS of the substrate SUB. That is, the lower surface LS of the substrate SUB may be divided into an inner area and an outer area by the groove GV on a plane.

The groove GV may include a first edge G-EG1 adjacent to an edge S-EG of the lower surface LS of the substrate SUB and a second edge G-EG2 disposed far from the edge S-EG of the lower surface LS. A width of the groove GV defined as a distance between the first edge G-EG1 and the second edge G-EG2 may be equal to or smaller than 10 μm.

The light shielding layer LSL may be disposed on the lower surface LS of the substrate SUB. The light shielding layer LSL may have a shape of which a thickness decreases as it approaches the edge. In the specification, an area in which the thickness of the light shielding layer LSL is constant is defined as a first area LSA-1, and an area in which the thickness of the light shielding layer LSL is decreased is defined as a second area LSA-2.

The light shielding layer LSL may be filled in the inner area of the substrate SUB and at least a portion of the groove GV. The first area LSA-1 overlaps the inner area of the substrate SUB and does not overlap the groove GV. A portion of the second area LSA-2 overlaps a portion of the groove GV. For example, an area in which the light shielding layer LSL is filled in the groove GV may be a partial area of the groove GV adjacent to the inner area of the substrate SUB or may be the entire area of the groove GV.

The light shielding layer LSL may have a light shielding effect only when the light shielding layer LSL has a predetermined thickness or more. This thickness may be changed depending on a light-shielding material and an actual product model. The second area LSA-2 has a low light shielding effect, and thus light may leak. That is, as the second area LSA-2 becomes smaller, and the first area LSA-1 becomes larger, the light shielding effect becomes higher.

In the substrate SUB on which the groove GV is defined, the light shielding material may be applied while filling the groove GV, and thus the second area LSA-2 may be formed narrowly. The second area LSA-2 may be formed narrowly, and the first area LSA-1 may be formed widely.

When a width of the second area LSA-2 in the second direction DR2 is constant, as the first edge G-EG1 of the groove GV becomes closer to the edge S-EG of the lower surface LS, the first area LSA-1 may be formed wider. A distance between the edge S-EG of the lower surface LS and the first edge G-EG1 may be in a range of 0 mm to 0.4 mm. Although not illustrated, the distance between the edge S-EG of the lower surface LS and the second edge G-EG2 may be 0 mm. In this case, the first edge G-EG1 of the groove GV may be defined as the edge S-EG of the substrate SUB. When the first edge G-EG1 is located at the edge S-EG of the substrate SUB, the first area LSA-1 may be the largest, and thus the light shielding effect of the light shielding layer LSL may be the highest.

This drawing highlights the groove GV to describe the groove GV, but an actual size and an actual location thereof may differ from those of the drawing. The width and a cross section of the groove GV may be changed depending on a laser radiation method, and are not limited to the present illustration.

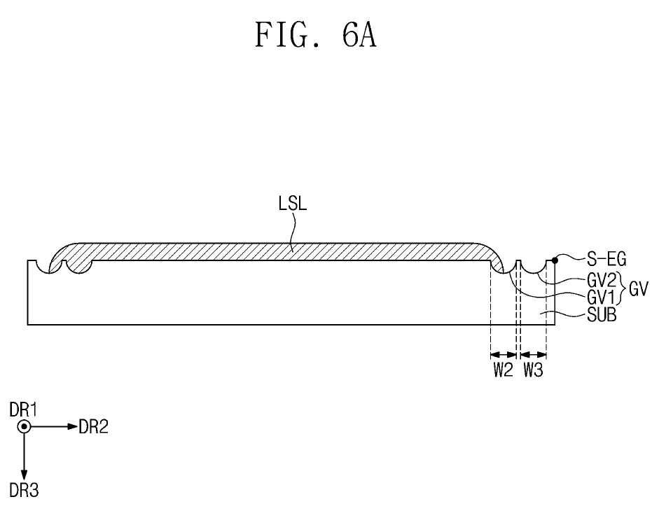

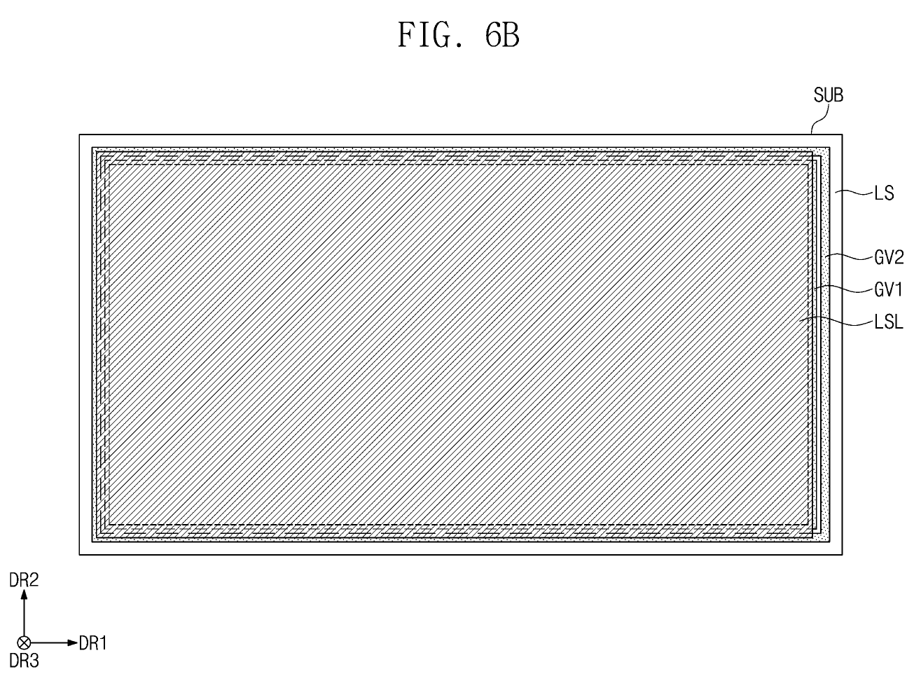

FIG. 6A is an enlarged cross-sectional view of the portion of the display device according to an embodiment, and FIG. 6B is a rear view of the portion of the display device according to an embodiment.

Referring to FIG. 6A, the substrate SUB may include a first groove GV1 and a second groove GV2. The second groove GV2 defines a groove closer to the edge S-EG of the substrate SUB than the first groove GV1. Referring to FIG. 6B, the first groove GV1 and the second groove GV2 each have a closed-loop shape on a plane on the lower surface LS of the substrate SUB.

A width W2 of the first groove GV1 may be equal to or smaller than 10 μm. A width W3 of the second groove GV2 may be equal to or smaller than 10 μm. The first groove GV1 and the second groove GV2 may have the same width or different widths. A depth of each of the first groove GV1 and the second groove GV2 may be in a range of 10 μm to 50 μm.

An edge of the first groove GV1, adjacent to the edge S-EG of the substrate SUB, and an edge of the second groove GV2, far from the edge S-EG of the substrate SUB, may be spaced part from each other as illustrated. However, as an example, the two edges may be defined as one edge. As another example, the first groove GV1 and the second groove GV2 may overlap each other. In this case, a portion, at which the first groove GV1 and the second groove GV2 meet each other, may be formed to have a thickness smaller than that of the substrate SUB.

A partial area of the light shielding layer LSL may overlap one of the first groove GV1 and the second groove GV2. Referring to FIGS. 6A and 6B, the light shielding layer LSL is applied while biased to the left side as a whole. Even when the light shielding layer LSL is non-uniformly applied, the light shielding layer LSL may overlap the second groove GV2 on a left side thereof and may overlap the first groove GV1 on a right side thereof. Thus, the two grooves GV may be included, and even when the light shielding layer LSL is non-uniformly applied, the light shielding layer LSL may overlap any one groove GV. Defect probability that the light shielding layer LSL is applied wider than the substrate SUB may be reduced.

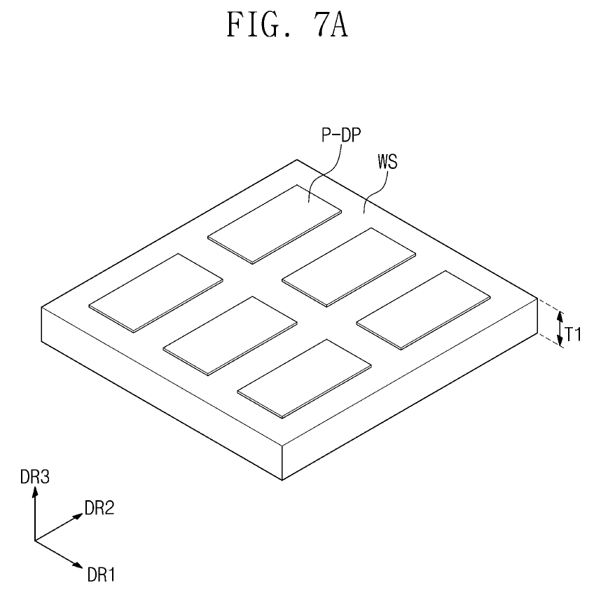

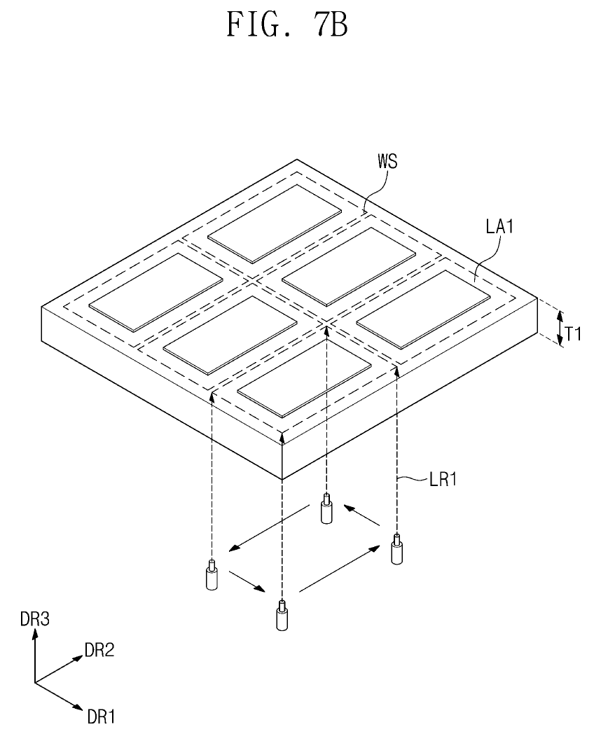

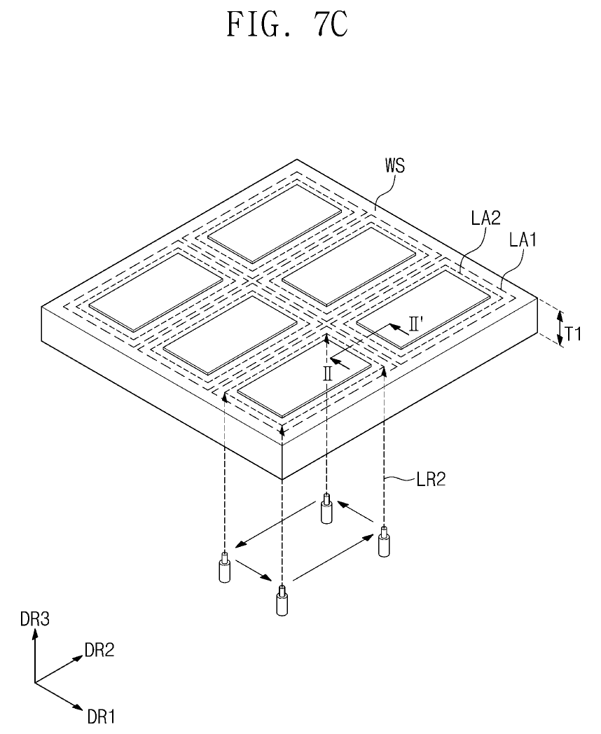

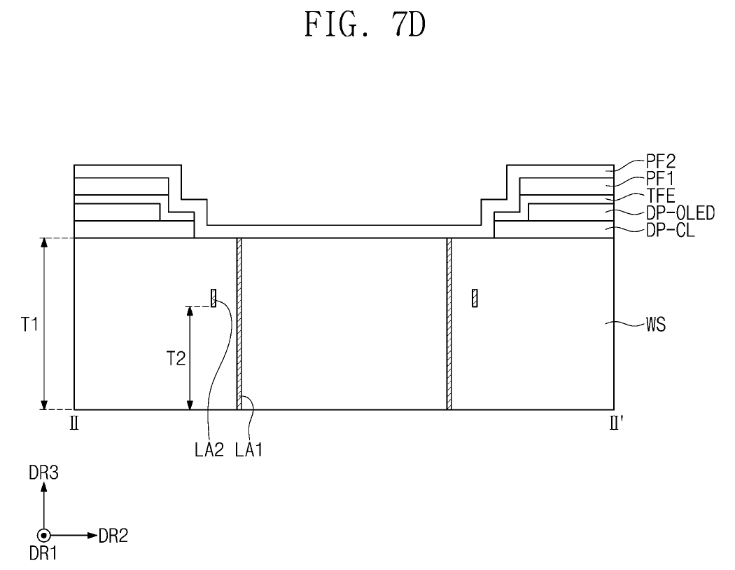

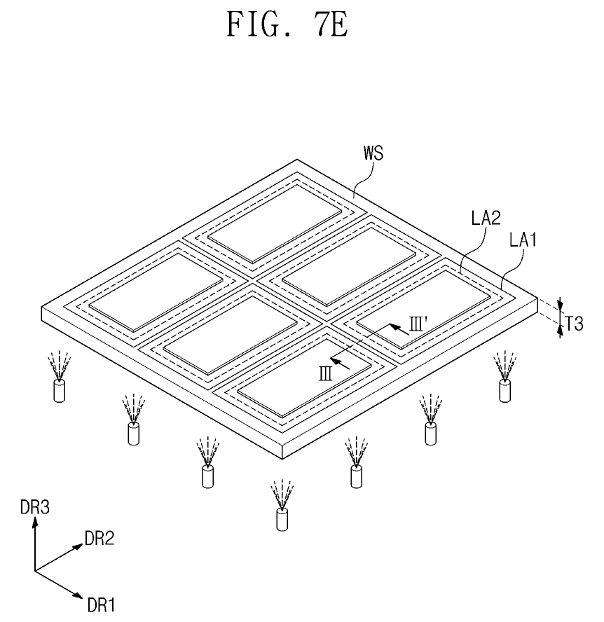

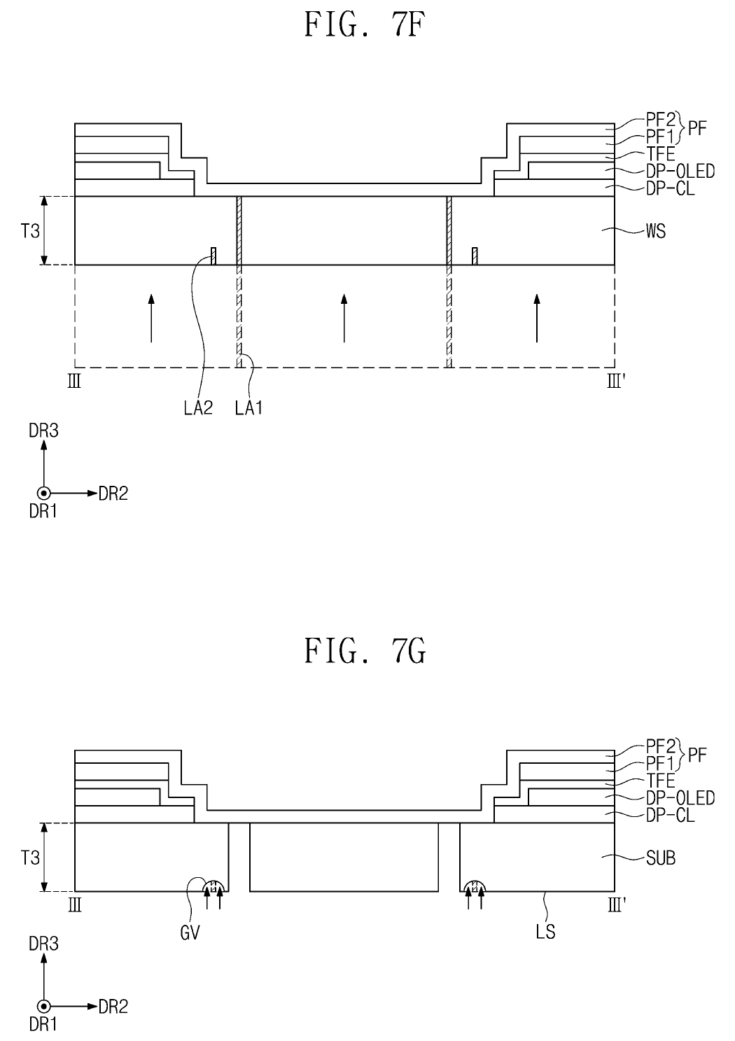

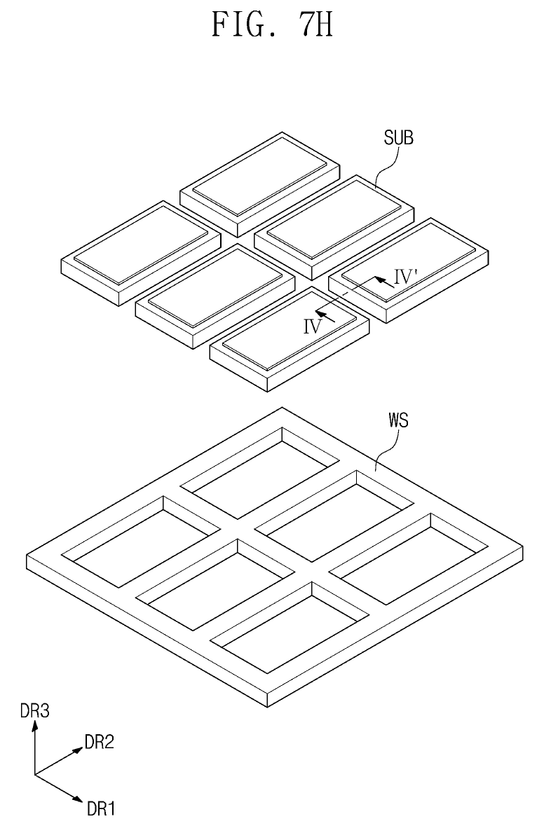

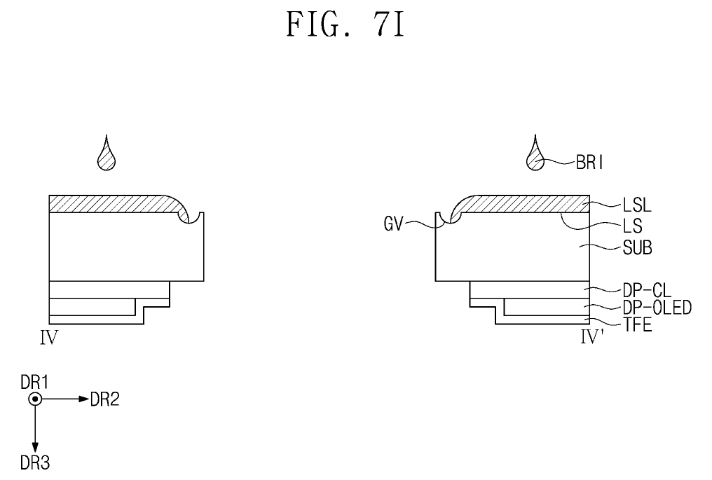

FIGS. 7A to 7I are cross-sectional views illustrating a method of manufacturing a display device according to an embodiment of the present disclosure. In description of FIGS. 7A to 7I, the same/similar components will be described using the same/similar reference numerals with reference to FIGS. 1 to 6, and thus duplicated descriptions thereof will be omitted.

Referring to FIG. 7A, a working substrate WS is provided. The working substrate WS may be a glass substrate. A thickness T1 of the working substrate WS may be about 0.5 mm.

The circuit element layer DP-CL (see FIG. 4) and the light emitting element layer DP-OLED (see FIG. 4) may be formed on each of a plurality of cell areas such that the working substrate WS has the plurality of cell areas. Each of the plurality of cell areas may form a preliminary display panel P-DP. The preliminary display panel P-DP may include the thin film encapsulation layer TFE in addition to the circuit element layer DP-CL (see FIG. 4) and the light emitting element layer DP-OLED (see FIG. 4). Protective films PF1 and PF2 (see FIG. 7D), which will be described below, may be attached to upper portions of the working substrate WS and the preliminary display panel P-DP.

Referring to FIG. 7B, a first laser LR1 may be radiated to a lower surface of the working substrate WS in the third direction DR3. An area radiated by the first laser LA1 corresponds to each cell area. Referring to FIG. 7C, a second laser LR2 may be radiated to the lower surface of the working substrate WS in the third direction DR3. An area radiated by the second laser LA2may be formed along the area radiated by the first laser LA1. The area radiated by the second laser LA2 may be formed inside each of the plurality of cell areas on the lower surface of the working substrate WS compared to the area radiated by the first laser LA1. The area radiated by the second laser LA2 may form a closed-loop on a plane. Here, the area to which the laser is radiated refers to an area to which the laser is radiated to provide a physical change to glass, and in this process, a hole may pass through or be partially formed in the glass.

FIG. 7D is a cross-sectional view corresponding to line II-II′ of the working substrate WS of FIG. 7C. The circuit element layer DP-CL, the light emitting element layer DP-OLED, and the thin film encapsulation layer TFE may be arranged on the working substrate WS. The first protective film PF1 is attached to an upper portion of the thin film encapsulation layer TFE, and the second protective film PF2 is attached to upper portions of the first protective film PF1 and the working substrate WS.

The area radiated by the first laser LA1 to which the first laser LR1 is radiated may be formed through the working substrate WS. The area radiated by the second laser LA2 to which the second laser LR2 is radiated may be formed at a constant depth T2 from the lower surface of the working substrate WS. The area radiated by the second laser LA2 to which the second laser LR2 is radiated may be formed by focusing and radiating the second laser LR2 at a constant depth of the working substrate WS. The depth T2 at which the area radiated by the second laser LA2 to which the second laser LR2 is radiated is formed may correspond to three fifths (3/5) of the thickness T1 of the working substrate WS. The depth T2 at which the area radiated by the second laser LA2 to which the second laser LR2 is radiated is formed may be about 0.3 mm. The first laser LR1 (see FIG. 7B) may have at least one of a processing speed, a repetition rate, and an output intensity of a laser, which is greater than that of the second laser LR2 (see FIG. 7C).

The area radiated by the second laser LA2 to which the second laser LR2 is radiated may be formed to have a thickness of about 10 μm to about 50 μm. A thickness of the area radiated by the second laser LA2 to which the second laser LR2 is radiated may correspond to the depth of the groove GV (see FIG. 7G).

Referring to FIG. 7E, the working substrate WS may be etched so that the cell substrate SUB corresponding to each of the plurality of cell areas is separated from the working substrate WS. A cell substrate SUB can be any one of a plurality of substrates separated from a working substrate WS. A cell substrate SUB may be the substrates of FIG. 4 through FIG. 6B. FIG. 7E illustrates, as an example, that a plurality of nozzles may be arranged below the working substrate WS, and the lower surface of the working substrate WS may be etched by an etchant sprayed from the nozzles. As the etchant is sprayed, a thickness T3 of the working substrate WS may be generally decreased. The decreased thickness T3 of the working substrate WS may correspond to two fifths (2/5) of the thickness T1 of the working substrate WS before the etching. The decreased thickness T3 of the working substrate WS may be about 0.2 mm.

FIGS. 7F and 7G are cross-sectional views corresponding to line III-III′ of the working substrate WS of FIG. 7E. Referring to FIG. 7F, the working substrate WS may be etched and thinned as the etchant is sprayed. The working substrate WS may be etched up to a point at which the thickness T3 is 2/5 of the thickness T1 before the etching. As a thickness of the working substrate WS is thinned, the area radiated by the second laser LA2 to which the second laser LR2 (see FIG. 7C) is radiated may be exposed.

Referring to FIG. 7G, the area radiated by the first laser LA1 (see FIG. 7F) to which the first laser LR1 is radiated may be etched so that the cell substrate SUB is separated from the working substrate WS. A lower surface of the cell substrate SUB may also be etched along the area radiated by the second laser LA2 to which the second laser LR2 (see FIG. 7C) is radiated. As the area radiated by the second laser LA2 to which the second laser LR2 is radiated is further etched, the groove GV may be formed.

Referring to FIG. 7H, the protective film PF (see FIG. 7G) may be removed, and the cell substrate SUB may be separated from the working substrate WS.

FIG. 7I is a cross-sectional view corresponding to line IV-IV′ of the cell substrate SUB of FIG. 7H. Referring to FIG. 7I, a black resin ink BRI may be applied to the lower surface of the separated cell substrate SUB. The black resin ink BRI may be applied to a center of the cell substrate SUB in an inkjet method. The black resin ink BRI may be spread around the applied area and applied to the lower surface of the cell substrate SUB. In this process, a partial area of the groove GV may be filled. As the groove GV is formed along the edge of the substrate SUB, a boundary of the black resin ink BRI may be constantly limited. The black resin ink BRI may be evenly applied to a target area without overflowing from an area of the cell substrate SUB. As the black resin ink BRI is applied, the light shielding layer LSL overlapping at least a partial area of the groove GV may be formed.

After the second laser LR2 (see FIG. 7C) is radiated, a third laser may be radiated. The area to which the third laser is radiated may be formed inside the cell area. The area to which the third laser is radiated may be formed inside the cell area along the area radiated by the second laser LA2 to which the second laser LR2 is radiated as compared to the area radiated by the second laser LA2 to which the second laser LR2 is radiated. The area to which the third laser is radiated may form a closed-loop on a plane.

The area radiated by the second laser LA2 to which the second laser LR2 is radiated and the area to which the third laser is radiated may be arranged to be spaced part from each other on a plane and may be formed at the same depth from the lower surface of the working substrate WS. The second laser LR2 and the third laser may have the same processing speed, the same repetition rate, and the same output intensity. The area to which the third laser is radiated may define a groove disposed inside a groove defined by the area radiated by the second laser LA2 to which the second laser LR2 is radiated. As a result, the substrates of FIGS. 6A and 6B may be formed.

In a display device according to an embodiment of the present disclosure, a light shielding layer may be disposed on a glass substrate on which a groove is defined. The light shielding layer may be filled to overlap the groove defined along an edge of the glass substrate, an area of the light shielding layer, of which a thickness is smaller than the standard, may be reduced, and thus light leakage may be reduced. Display performance may be improved due to the reduced light leakage.

Since an edge of the light shielding layer is defined by the groove defined along the edge of the glass substrate, the light shielding layer may be uniformly formed. Since the edge of the light shielding layer is easily controlled by the groove, the light shielding layer may be formed thicker. Strength of a substrate may be increased, and damage to and breakage of the substrate may be minimized.

According to an embodiment, a method of manufacturing a display device may include forming a circuit element layer and a light emitting element layer in each of a plurality of cell areas of a working substrate, radiating a first laser to a lower surface of the working substrate to correspond to the plurality of cell areas, radiating a second laser into each of the plurality of cell areas on the lower surface of the working substrate along an area to which the first laser is radiated as compared to the area to which the first laser is radiated, etching the working substrate so that a cell substrate corresponding to each of the plurality of cell areas is separated from the working substrate, and forming a light shielding layer on a lower surface of the cell substrate, wherein, in the etching of the working substrate, the area to which the first laser is radiated defines an edge of the lower surface of the cell substrate, and an area to which the second laser is radiated defines a groove disposed inside the edge of the lower surface of cell substrate, and the light shielding layer is located on at least a partial area of the groove.

According to an embodiment of the present disclosure, the method may further include etching the lower surface of the working substrate to the area to which the second laser is radiated after radiating the second laser, and further etching the lower surface of the cell substrate along the area to which the second laser is radiated.

According to an embodiment of the present disclosure, the second laser may be radiated so that the area to which the second laser is radiated forms a closed loop on a plane.

According to an embodiment of the present disclosure, the first laser may be radiated to pass though the working substrate, and the second laser may be radiated to the area to which the second laser is radiated at the same depth from the lower surface of the working substrate.

According to an embodiment of the present disclosure, the first laser may have at least one of a processing speed, a repetition rate, and an output intensity of a laser, which is greater than that of the second laser.

According to an embodiment of the present disclosure, the method may further include radiating a third laser along the area to which the second laser is radiated, wherein an area to which the third laser is radiated define a groove disposed inside the lower surface of the cell substrate.

According to an embodiment of the present disclosure, the area to which the second laser is radiated and an area to which a third laser is radiated may be arranged to be spaced apart from each other and formed at the same depth from the lower surface of the cell substrate.

Although the description has been made above with reference to an embodiment of the present disclosure, the present disclosure is not limited to an embodiment and may be variously changed and modified within the spirit and scope of the present disclosure claimed below by those skilled in the art to which the present disclosure pertains.

What is claimed is:

1. A display device comprising:
a substrate comprising an upper surface and a lower surface opposite the upper surface, the substrate comprising a groove extending along an edge of the lower surface;
a light emitting element layer on the upper surface; and
a light shielding layer on the lower surface, at least a portion of the light shielding layer being in at least a portion of the groove.

2. The display device of claim 1, wherein the groove divides the lower surface into an inner area and an outer area, and
wherein the light shielding layer is in the inner area.

3. The display device of claim 1, wherein the light shielding layer comprises the same thickness in an area not overlapping the groove.

4. The display device of claim 1, wherein the groove comprises a width of about 10 μm.

5. The display device of claim 1, wherein the groove comprises a closed-loop shape in a plan view of the lower surface of the substrate.

6. The display device of claim 1, wherein the groove comprises a first edge adjacent the edge of the lower surface and a second edge disposed farther from the edge of the lower surface than the first edge, and
wherein a distance between the edge of the lower surface and the first edge is about 0.4 mm or less.

7. The display device of claim 1, wherein the light shielding layer comprises a base resin and a black component mixed with the base resin.

8. The display device of claim 1, wherein the groove comprises a first groove and a second groove, and
wherein the second groove is closer to an edge of the substrate than the first groove.

9. The display device of claim 8, wherein each of the first groove and the second groove comprises a width of about 10 μm.

10. The display device of claim 8, wherein a partial area of the light shielding layer overlaps any one of the first groove or the second groove.

11. An electronic device comprising:
a display device; and
a processor configured to control the display device;
wherein the display device comprises:
a substrate comprising an upper surface and a lower surface opposite the upper surface, the substrate comprising a groove adjacent an edge thereof;
a light emitting element layer on the upper surface; and
a light shielding layer on the lower surface,
wherein a partial area of the light shielding layer overlaps a partial area of the groove.

12. The electronic device of claim 11, wherein the groove comprises a closed-loop shape in a plan view of the lower surface of the substrate.

13. The electronic device of claim 11, wherein the groove comprises a width of about 10 μm.

14. A method of manufacturing a display device, the method comprising:
forming a circuit element layer and a light emitting element layer in each of a plurality of cell areas of a working substrate;
radiating a first laser to a lower surface of the working substrate corresponding to the plurality of cell areas;
radiating a second laser into each of the plurality of cell areas on the lower surface of the working substrate along an area radiated by the first laser;
etching the working substrate so that a cell substrate corresponding to each of the plurality of cell areas is separated from the working substrate; and
forming a light shielding layer on a lower surface of the cell substrate,
wherein in the etching of the working substrate, the area radiated by the first laser comprises an edge of the lower surface of the cell substrate, and an area radiated by the second laser comprises a groove inside the edge of the lower surface of the cell substrate, and
wherein the light shielding layer is on at least a partial area of the groove.

15. The method of claim 14, further comprising:
after radiating the second laser, etching the lower surface of the working substrate in the area radiated by the second laser; and
further etching the lower surface of the cell substrate along the area radiated by the second laser.

16. The method of claim 14, wherein the second laser is radiated so that the area radiated by the second laser forms a closed loop in a plan view of the lower surface of the cell substrate.

17. The method of claim 14, wherein the first laser is radiated to pass though the working substrate, and
wherein, along the area radiated by the second laser, the second laser is radiated at the same depth from the lower surface of the working substrate.

18. The method of claim 14, wherein the first laser comprises at least one of a processing speed, a repetition rate, and an output intensity of a laser, which is greater than that of the second laser.

19. The method of claim 14, further comprising:
radiating a third laser along the area radiated by the second laser,
wherein an area radiated by the third laser comprises a groove inside the lower surface of the cell substrate.

20. The method of claim 14, wherein the area radiated by the second laser and an area radiated by a third laser are spaced apart from each other and at the same depth from the lower surface of the cell substrate.
